(19) United States
(12) Patent Application Publication
(10) Pub. No.: US 2008/0026593 A1
(43) Pub. Date: Jan. 31, 2008

(54) Method and Apparatus for the Manufacture of Electric Circuits

(76) Inventor: William Ogilvie, Hertfordshire (GB)

Correspondence Address: WELSH & FLAXMAN LLC, 2000 DUKE STREET, SUITE 100, ALEXANDRIA, VA, 22314, US

(21) Appl. No.: 10/587,912

(22) PCT Filed: Oct. 1, 2004
(86) PCT No.: PCT/GB04/04205

§ 371 Date: Apr. 19, 2007

(30) Foreign Application Priority Data
Oct. 30, 2003 (GB) 0325371.3

(51) Int. Cl. H01L 21/31

(52) U.S. Cl. 438/763; 427/97.1

(57) ABSTRACT

A method of manufacturing a patterned electric circuit. The method comprises the steps of providing a cold gas-dynamic spraying (CGDS) device, providing a substrate, and depositing a pattern of electrically conductive material with the CGDS device on the substrate by relative movement between the CGDS device to the substrate.

The invention relates to a method and apparatus for the manufacture of patterned electric circuits.

Currently, electric circuits are produced in a variety of ways including by print stamping and etching.

Traditional PCB production requires a sheet of a conductive material. An etch resistant substance is used to cover the desired circuit pattern and the excess conductive material is etched away.

The known Bus-Bar method also requires a sheet of conductive material. A metal stamp with the circuit pattern design is used to stamp out the desired circuit pattern.

Both of these methods produce excess waste materials as they involve starting from a complete sheet of conductive material and removing a large amount of it to leave the patterned circuit design. These methods also require circuit pattern-specific tooling which can be costly and time consuming to produce and which is difficult to adapt if a circuit design changes.

Also, the circuits produced by these methods are typically flat, and it is difficult to apply these methods to a three-dimensional surface.

Other methods that have been suggested for the production of patterned electric circuits include thermal spraying techniques such as flame spraying, plasma spraying and the use of high velocity Oxy Fuel. These techniques use a mask with the desired circuit pattern. Material is sprayed onto the mask which is then removed to leave sprayed material in the circuit pattern design.

This method also involves producing a large quantity of waste material which is removed with the mask. It again additionally requires circuit pattern-specific tooling which is costly and time consuming to produce and difficult to adapt if a circuit design changes.

In addition, the thermal spraying methods identified above involve spraying the conductive material in a molten or semi-molten state. This introduces undesirable features or characteristics in the material being sprayed, such as phase changes, increases in oxide content and reductions in ductility. This is detrimental to the performance of the circuit formed and can result in increased resistance and reduced tolerance to changes in environmental conditions such as vibration and temperature change.

Once a conventional circuit has been produced, components are usually connected to it by soldering. This requires additional materials, such as solder and additional processing steps, such as passing the circuit through a solder bath. It can be expensive and time consuming and care must be taken to ensure that the components are soldered in the right place.

The present invention aims to address some of the problems described above that are experienced with conventional methods of circuit manufacture.

According to the present invention there is provided a method of manufacturing a patterned electric circuit, the method comprising the steps of:
providing a cold gas-dynamic spraying (CGDS) device,
providing a substrate,
and depositing a pattern of electrically conductive material with the CGDS device on the substrate by relative movement between the CGDS device to the substrate, wherein prior to depositing the pattern of electrically conductive material, the CGDS device is used to deposit a bond layer.

According to the present invention there is also provided an pparatus for manufacturing a patterned electric circuit the apparatus comprising:
a drive mechanism;
a cold gas-dynamic spraying (CGDS) device; and
means for controlling, in use, the device mechanism to provide relative movement between the CGDS device and a substrate to deposit a bond layer on the substrate and a pattern of electrically conductive material on the bond layer.

CGDS devices can produce a very well defined spray pattern with limited overspray. This results in the possibility of manufacturing a patterned electric circuit board using little or no masking. Hence, the present invention provides a method for manufacturing patterned electric circuits with a dramatic reduction in waste material compared with conventional methods. It reduces and in some cases eliminates, the need for circuit specific tooling, for example, masks, stamping elements, or etching elements hence reducing the cost and extra process steps associated with such tooling.

CGDS devices can maintain a temperature below the melting point of the material to be sprayed. Hence, the characteristics of the deposited conductive material are greatly improved compared to the use of high heated spray processes.

The bond layer greatly increases the bond strength of the circuit with the substrate. Another advantage of a bond layer is that it allows for a very wide range of substrate materials to be used.

In addition, the present invention allows for the electric components to be connected to the substrate easily and without costly and lengthy soldering procedures.

In a preferred embodiment of the invention the CGDS device can be used when an electric component is to be included in the circuit. This method provides for the electric component to be both held in place and electrically connected to the circuit.

In a further embodiment of the present invention, multiple layers of electric circuits can be built up with a dielectric material layer between them. In this way, highly complex circuits can be manufactured in a hugely reduced space and with relative ease compared to conventional methods.

Furthermore, the present invention can be applied to a three-dimensionally contoured substrate. This opens up many new and exciting possibilities as an electric circuit can be sprayed onto practically any surface. An example of one such possibility is in the car manufacturing industry where, using the present invention, an electric circuit can be sprayed directly onto the shell of a car door for use in operating an electric window. Previously, a circuit and some means of holding it in place in the car door would be produced separately and assembled in the door. There are many industries where this invention could be used in a similar way with advantages in terms of cost, process efficiency and space efficiency over conventional methods.

The present invention will now be described in more detail with reference to the accompanying drawings, in which:

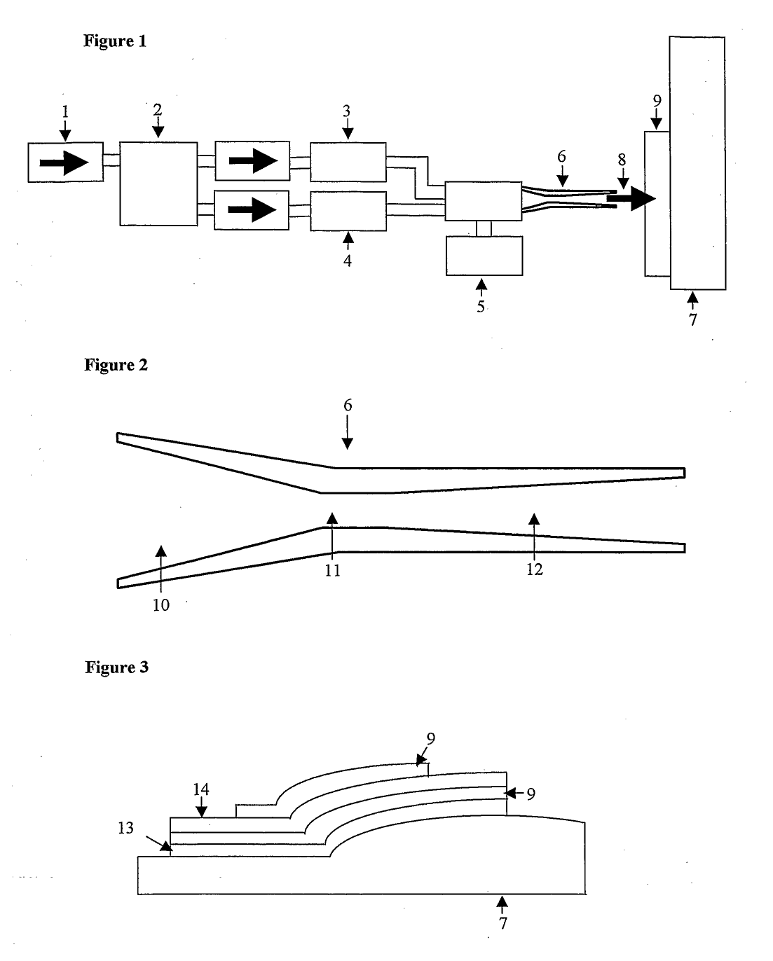

FIG. 1 is a schematic diagram of CGDS device as used in the present invention;

FIG. 2 is a cross sectional view of the nozzle of a CGDS device as used in the present invention;

FIG. 3 is a cross sectional view of a multi-layered circuit manufactured by the present invention;

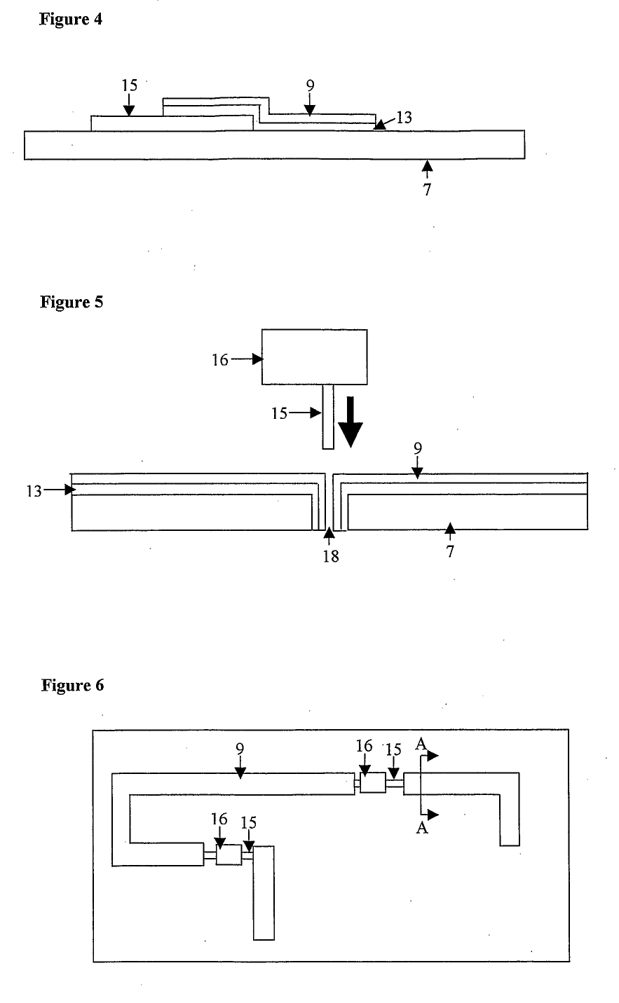

FIG. 4 is a cross sectional view of circuit including an electric component manufactured by the present invention;

FIG. 5 is a cross sectional view of a circuit manufactured by the present invention and an electric component to be connected to the circuit;

FIG. 6 is a plan view of a circuit including electric components manufactured by the present invention;

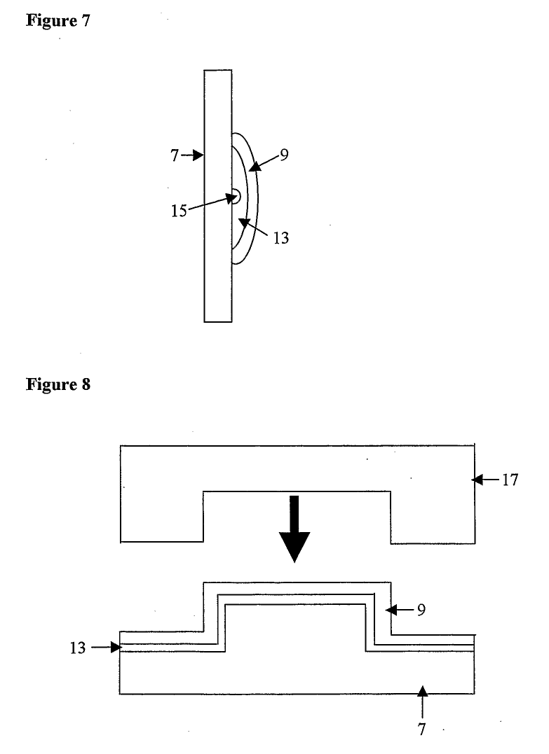

FIG. 7 is a cross sectional view through the circuit of FIG. 6 along the plane A -A; and

FIG. 8 is a cross section through a circuit manufactured by the present invention and a connecting component to be connected to the circuit.

Prior to describing the invention it is appropriate to discuss some of the broader principles that it employs. Cold gas dynamic spraying (CGDS) involves introducing powder particles into a gas flow and accelerating the mixture to form a supersonic jet. The jet is directed at a substrate and the powder particles are deposited on the surface of the substrate. CGDS devices suitable for use in this invention are known for applying coatings to various materials as described, for example, in US-A-5302414.

As shown in FIG. 1, a CGDS device includes a compressed gas supply 1. The gas is, in this example, nitrogen but can be other gases, such as helium. From the compressed gas supply 1, the gas flows through a gas line to a gas control unit 2. The pressure of the gas leaving the gas control unit is typically 0.5 to 5 MPa, preferably 2 to 4 MPa, most preferably about 3 MPa. The gas then also flows into to a powder feeder 3 where powder particles are introduced to form an gas/particle jet. The powder feeder 3 comprises a powder feedstock and a metering component (not shown).

The powder feedstock contains powder particles of an electrically conductive material such as copper, aluminium, silver, gold, nickel, tin, zinc or alloys of these materials. Copper has particular benefits but any electrically conducting material can be used. According to alternative embodiments of the invention the powder feedstock can contain particles of a bond material, a dielectric material or any other material to be deposited on the substrate 7 and that is suitable for use with a CGDS device. The size of the particles are typically in the range from 1 to 50 μm across.

The metering component is used to regulate and control the feed rate of particles into the gas flow. A feed rate of between 2.4 and 15 kg/hr is generally used. Any suitable metering component can be used, for example that described in US-A-5302414.

The temperature of the gas is below the melting temperature of the respective electrically conductive material being sprayed and in practice is between 0 and 600° C. The CGDS device optionally includes a gas heater 4 which can be used as one method to control the velocity of the jet. An increased temperature can increase the velocity of the jet and can also improve the ductility of the electrically conductive material.

The gas/particle jet travels to a nozzle 6 which has three sections, a convergent section 10, a throat section 11 and a divergent section 12 (see FIG. 2). The jet enters the convergent section 10 first which compresses the gas causing it to accelerate to a velocity of approximately 332 m/sec (mach 1). The jet then enters the throat section 11 where the velocity of the jet is maintained at approximately 332 m/sec (mach 1). The third and exit section of the nozzle 12 is divergent and in this section the gas expands to nominal atmospheric pressure causing the jet to accelerate further to a velocity of between 400 and 1200 m/s.

The dimensions and shape of the nozzle are important as they have a large effect on the properties of the exiting jet. The jet 8 needs to have a supersonic velocity on leaving the nozzle 6 so that the particles become firmly deposited on the substrate 7. The ratio of the throat area 11 to the divergent area 12 is important in ensuring the jet is accelerated to the required velocity. In this example, an area ratio of between 1.5 and 10 is used.

The design of the nozzle also determines the profile of the supersonic jet produced and the nozzle is designed to produce a fine and well defined spray. The nozzle design can be changed to produce a spray profile which is most suitable for the the circuit being produced.

The supersonic jet 8 is directed at a substrate 7 and the electrically conductive material is deposited 9 on the surface of the substrate 7. The substrate 7 can be made of any supportive material, for example, a metal or a polymer. In the case of a metallic substrate, a dielectric insulating coating would be required which could be in the form of a thermally sprayed ceramic coating, a polymer coating or any other suitable coating. The substrate 7 can be flat or can be a contoured three-dimensional shape (as illustrated in FIG. 3).

To create a pattern of electrically conductive material on the substrate, the CGDS device is moved relative to the substrate 7 or vice verse. In practice this is done by mounting the CGDS device on a drive mechanism 5 such as a robot or X-Y plotter. The CGDS device can be mounted by any suitable means. In this example the drive mechanism is a robot or X-Y plotter, but any suitable manipulation means can be used. The drive mechanism 5 may be operated manually, but in this example is preprogrammed to produce the desired patterned design.

To improve the bond strength of the deposited electrically conductive material 9 with the substrate 7, an intermediate bond layer 13 can be used (see FIG. 3). This is particularly useful when the substrate is a polymeric material. The bond layer 13 is created using the CGDS device prior to depositing the electrically conductive material. The bond layer 13 can be deposited as a coating or can be deposited in the pattern of the circuit to be produced, ie. only where it is needed. Suitable materials for use as bonding layers include low melting materials, such as tin, zinc, lead, bismuth or alloys of these materials.

In one embodiment of the invention, after depositing the pattern of electrically conductive material 9, the CGDS device can be used to deposit a layer of dielectric material 14 and then a second pattern of electrically conductive material 9 (see FIG. 3). The method of the present invention is very flexible and multiple layers, usually of alternating conductive and dielectric materials, can be produced. The drive mechanism 5 can be programmed to deposit each layer in any desired pattern, or to provide a complete or partial coating. Openings 18 between some or all of the layers can be left to create contact points which can be used to include electric components 16 in the circuit (see FIG. 5). Such layering can be used to build up an electric circuit of any desired shape. This is extremely useful where, for example, the patterned electric circuit is just one component in a larger device and can be manufactured to fit well with other components.

The present invention allows for complicated circuits to be manufactured on an individual basis relatively cheaply, as pattern specific tooling is not required. The drive mechanism 5 can be programmed to create any pattern and the powder feedstock can be changed to particles of many different materials. Hence, highly complex circuits can be produced by the method and apparatus of the present invention.

The present invention also provides a convenient method of connecting the electric circuit 9 with electric components 16. An electric component 16 is placed on the substrate 7 and the CGDS device is used to deposit a bond layer 13 and/or a pattern of conductive material 9 on the electric component 16 as well as on the substrate 7 as shown in FIG. 4. Such components usually have connection parts 15, commonly referred to as legs, which in conventional manufacturing methods would be soldered to the substrate. To integrate an electric component 16 into the circuit, the CGDS device is used to spray a bond layer 13 and/or an electrically conductive material 9 on to the connection part of the electronic component. This has the effect both of holding the component in place, and electrically connecting the component with the patterned circuit. When multiple layers are formed, the electric component can be integrated with any or all of the layers.

FIG. 6 shows an electric circuit of deposited electrically conductive material 9 that has electric components 16 attached in place in the circuit by legs 15. FIG. 7, a cross section through plane A-A of FIG. 6, shows that the legs 15 are connected to the substrate by a bond layer 13, coated with an electrically conductive layer 9. FIG. 8 shows how a circuit can be manufactured on a shaped substrate 7 to allow it to fit neatly with a connecting component 17.

1. A method of manufacturing a patterned electric circuit, the method comprising the steps of:
providing a cold gas-dynamic spraying (CGDS) device,
providing a substrate,
and depositing a pattern of electrically conductive material with the CGDS device on the substrate by relative movement between the CGDS device to the substrate, wherein prior to depositing the pattern of electrically conductive material, the CGDS device is used to deposit a bond layer.

2. The method of claim 1, wherein the electrically conductive material is copper or a copper alloy.

3. The method of claim 1, wherein the bond layer comprises tin, a tin alloy, zinc or a zinc alloy.

4. The method of claim 1, wherein an electric component is placed on the substrate and the CGDS device is used to deposit a bond layer and/or electrically conductive material on the electric component.

5. The method of claim 4, wherein the bond layer and/or electrically conductive material is deposited on the connection part of the electric component.

6. The method of claim 1, wherein, after depositing the pattern of electrically conductive material, the CGDS device is used to deposit a layer of dielectric material and then a second pattern of electrically conductive material.

7. The method of claim 1, wherein the substrate has a three-dimensional contoured shape.

8. (canceled)

9. Apparatus for manufacturing a patterned electric circuit the apparatus comprising:
a drive mechanism;
a cold gas-dynamic spraying (CGDS) device; and
means for controlling, in use, the device mechanism to provide relative movement between the CGDS device and a substrate to deposit a bond layer on the substrate and a pattern of electrically conductive material on the bond layer.
